(19) United States
(12) Patent Application Publication
(10) Pub. No.: US 2017/0194188 A1
(43) Pub. Date: Jul. 6, 2017

(54) SUSCEPTOR DESIGN FOR EPI UNIFORMITY IMPROVEMENT

(71) Applicant: Taiwan Semiconductor Manufacturing Co., Ltd., Hsinchu (TW)

(72) Inventor: Shih-Wei Hung, Kaohsiung City (TW)

(21) Appl. No.: 14/984,732

(22) Filed: Dec. 30, 2015

(51) Int. Cl. H01L 21/687; C30B 25/12; C30B 23/02; C23C 16/458; C23C 16/46

(52) U.S. Cl. CPC H01L 21/68785; H01L 21/68757; C23C 16/4581; C23C 16/46; C30B 23/02; C30B 25/12

(57) ABSTRACT

A susceptor for use in an epitaxial growth chamber includes a thermally conductive body designed to hold a substrate. The body includes a first region, a second region, and a third region. The first region extends from an outer edge of the body inwards towards a center of the body at a first width, the first region having a first height. The second region extends from an inner edge of the first region inwards towards the center of the body at a second width, the second region having a second height lower than the first height. The third region extends from an inner edge of the second region to the center of the body. The second region includes a planar surface that is substantially parallel to a bottom surface of the substrate and a portion of the bottom surface of the substrate rests upon the planar surface.

### BACKGROUND

Epitaxial growth procedures are widely used to form various layers or structures of transistor devices. When forming such devices across the surface of a wafer, the temperature profile across the wafer can affect the growth rate of the epitaxial layer. One common issue with many semiconductor processes is known as the “edge effect” where devices located closer to the edge of a wafer suffer poor yield due to fabrication imperfections. The edge effect manifests during an epitaxial growth process as the growth rate changes more drastically closer to the edge of the wafer. This effect becomes even more noticeable as wafer size increases. To counteract this effect, different heat sources within the epitaxial growth chamber can be driven with higher current in an attempt to “even out” the temperature profile across the wafer. Unfortunately, this solution leads to a decreased life-span for the heat sources as well as a longer production time due to tuning of the heat source output for a given process.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a perspective view of an example semiconductor device structure, in accordance with some embodiments.

FIG. 1B shows a top view of an example transistor region, in accordance with some embodiments.

FIGS. 2A and 2B are cross-sectional views of an example transistor region, in accordance with some embodiments.

FIGS. 3A and 3B are cross-sectional views of an example transistor region after forming the doped source and drain regions, in accordance with some embodiments.

FIG. 4 is an illustration of an epitaxial growth chamber, according to an embodiment.

FIG. 5 is a graph illustrating epitaxial growth uniformity across a substrate.

FIG. 6 is a cross-sectional view of a susceptor, according to an embodiment.

FIGS. 7A and 7B illustrate top-down view of the susceptor, according to some embodiments.

FIG. 8 is a graph illustrating epitaxial growth uniformity across a substrate, according to an embodiment.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The acronym “FET,” as used herein, refers to a field effect transistor. A very common type of FET is referred to as a metal oxide semiconductor field effect transistor (MOSFET). Historically, MOSFETs have been planar structures built in and on the planar surface of a substrate such as a semiconductor wafer. But recent advances in semiconductor manufacturing have resulted in the use vertical structures.

The term “finFET” refers to a FET that is formed over a fin that is vertically oriented with respect to the planar surface of a wafer.

S/D refers to the source and/or drain junctions that form two of the four terminals of a FET.

The expression “epitaxial layer” herein refers to a layer or structure of single crystal semiconductor material. Likewise, the expression “epitaxially grown” herein refers to a layer or structure of single crystal semiconductor material. The shortened term “epi” may be used herein to stand for “epitaxial.”

The expression “high-k” refers to a high dielectric constant. For example, high-k refers to a dielectric constant that is greater than the dielectric constant of SiO₂ (i.e., greater than 3.9).

The term “vertical,” as used herein, means nominally perpendicular to the surface of a substrate.

Overview

Various embodiments in accordance with this disclosure provide designs for a susceptor that holds a substrate within an epi growth chamber. According to an embodiment, the susceptor is designed to support the substrate upon a substantially flat and planar shelf region, such that heat is transferred into the edge region of the substrate via thermal conduction. This heat transfer using conduction provides a more uniform temperature profile across the substrate surface, which improves the growth profile of an epitaxially grown layer across the substrate surface.

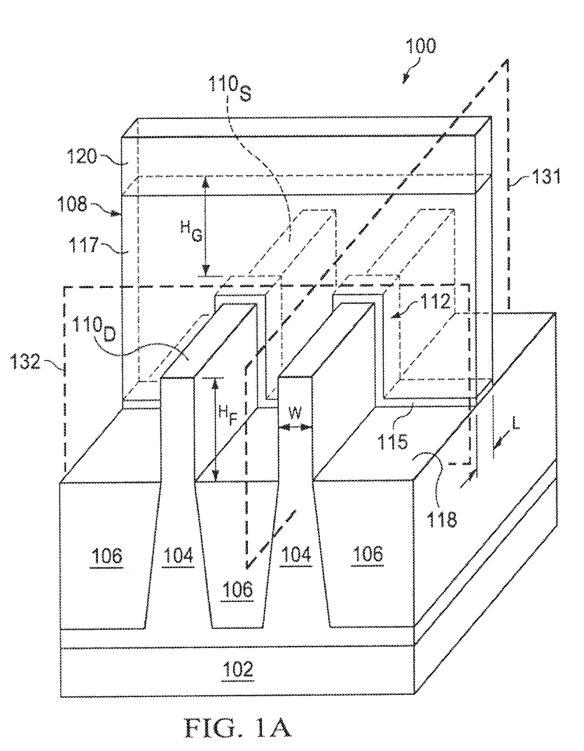

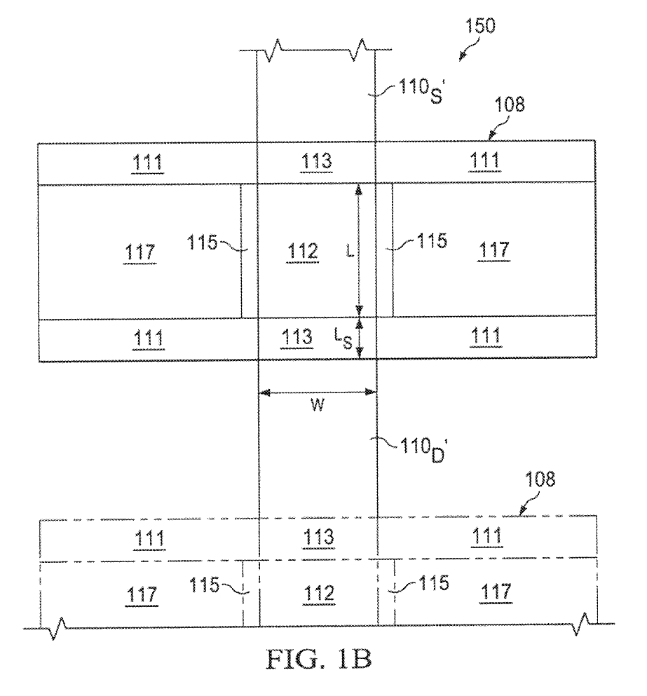

Before describing the embodiments related to the design of the susceptor, an example fabrication process for a finFET, which includes epitaxially grown S/D regions, is presented. FIGS. 1-3 provide various views of a semiconductor device that includes finFETs during various stages of fabrication. The fabrication process provided here is exemplary, and many other steps may be performed that are not shown in these figures.

Illustrated in FIG. 1A is perspective view of a semiconductor device structure 100, in accordance with some embodiments. The semiconductor device structure 100 includes finFET device structures. The semiconductor device structure 100 includes a substrate 102, a plurality of fins 104, a plurality of isolation structures 106, and a gate structure 108 disposed on each of the fins 104. The gate structure 108 may include a gate dielectric layer 115, a gate electrode layer 117, and/or one or more additional layers. A hard mask layer 120 is over the gate electrode layer 117. Hard mask layer 120 is used to pattern, such as by etching, the gate structure 108. In some embodiments, hard mask layer 120 is made of a dielectric material, such as silicon oxide. The perspective view of FIG. 1A is taken after the patterning (or forming) process of gate structure 108. FIG. 1A shows only one gate structure 108. There are additional gate structure(s) (not shown) similar and parallel to the gate structure 108 shown in FIG. 1A.

Each of the plurality of fins 104 includes a source region 110_{S} and a drain region 110_{D}, where source or drain features are formed in, on, and/or surrounding fin 104. A channel region 112 of fin 104 underlies gate structure 108. Channel region 112 of fin 104 has a length (gate length) L, and a width (gate width) W, as shown in FIG. 1A. In some embodiments, the length (gate length) L is in a range from about 10 nm to about 30 nm. In some other embodiments, the gate length L is in a range from about 3 nm to about 10 nm. In some embodiments, the width (gate width) W is in a range from about 10 nm to about 20 nm. In some other embodiments, the width (gate width) W is in a range from about 3 nm to about 10 nm. The height (gate height) H_{G} of gate structure 108, measured from the top of fin 104 to the top of gate structure 108, is in a range from about 50 nm to about 80 nm, in some embodiments. The height (fin height) H_{F} of fin 104, measured from the surface of isolation structure 106 to the top of fin 104, is in a range from about 35 nm to about 60 nm, in some embodiments.

The substrate 102 may be a silicon substrate. Alternatively, the substrate 102 may comprise another elementary semiconductor, such as germanium; a compound semiconductor including silicon carbide, gallium arsenide, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In an alternative embodiment, the substrate 102 is a semiconductor on insulator (SOI).

Isolation structures 106 is made of a dielectric material and may be formed of silicon oxide, silicon nitride, silicon oxynitride, fluoride-doped silicate glass (FSG), a low-k dielectric material, and/or other suitable insulating material. Isolation structures 106 may be shallow trench isolation (STI) features. In an embodiment, the isolation structures are STI features and are formed by etching trenches in substrate 102. The trenches may then be filled with isolating material, followed by a chemical mechanical polish (CMP). Other fabrication techniques for isolation structures 106 and/or fin structure 104 are possible. Isolation structures 106 may include a multi-layer structure, for example, having one or more liner layers.

Fin structures 104 may provide an active region where one or more devices are formed. In an embodiment, a channel region 112 of a transistor device is formed in fin 104. Fin 104 may comprise silicon or another elementary semiconductor, such as germanium; a compound semiconductor including silicon carbide, gallium arsenide, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Fins 104 may be fabricated using suitable processes including photolithography and etch processes. The photolithography process may include forming a photoresist layer (resist) overlying the substrate (e.g., on a silicon layer), exposing the resist to a pattern, performing post-exposure bake processes, and developing the resist to form a masking element including the resist. The masking element may then be used to protect regions of the substrate while an etch process forms a recesses into isolation structures 106, leaving protruding fins. The recesses may be etched using reactive ion etch (RIE) and/or other suitable processes. Numerous other embodiments of methods to form fins 104 on substrate 102 may be suitable.

Gate structure 108 may include a gate dielectric layer 115, a gate electrode layer 117, and/or one or more additional layers. In an embodiment, gate structure 108 is a sacrificial gate structure such as formed in a replacement gate process used to form a metal gate structure. In an embodiment, gate structure 108 includes a polysilicon layer (as gate electrode layer 117).

In an embodiment, gate structure 108 may be a metal gate structure. The metal gate structure may include interfacial layer(s), gate dielectric layer(s), work function layer(s), fill metal layer(s) and/or other suitable materials for a metal gate structure. In other embodiments, metal gate structure 108 may further include capping layers, etch stop layers, and/or other suitable materials. The interfacial layer may include a dielectric material such as silicon oxide layer (SiO2) or silicon oxynitride (SiON). The interfacial dielectric layer may be formed by chemical oxidation, thermal oxidation, atomic layer deposition (ALD), chemical vapor deposition (CVD), and/or other suitable formation process.

Exemplary p-type work function metals that may be included in gate structure 108 include TiN, TaN, Ru, Mo, Al, WN, ZrSi₂, MoSi₂, TaSi₂, NiSi₂, WN, other suitable p-type work function materials, or combinations thereof. Exemplary n-type work function metals that may be included in gate structure 108 include Ti, Ag, TaAl, TaAlC, TiAlN, TaC, TaCN, TaSiN, Mn, Zr, other suitable n-type work function materials, or combinations thereof. A work function value is associated with the material composition of the work function layer, and thus, the material of the first work function layer is chosen to tune its work function value so that a desired threshold voltage Vt is achieved in the device that is to be formed in the respective region. The work function layer(s) may be deposited by CVD, physical vapor deposition (PVD), and/or other suitable process. The fill metal layer may include Al, W, or Cu and/or other suitable materials. The fill metal may be formed by CVD, PVD, plating, and/or other suitable processes. The fill metal may be deposited over the work function metal layer(s), and thereby filling in the remaining portion of the trenches or openings formed by the removal of the sacrificial gate structure.

Semiconductor device structure 100 described above include fins 104 and gate structure 108. Semiconductor device structure 100 needs additional processing to form various features, such as lightly-doped-drain (LDD) regions and doped source/drain structures, of the transistor utilizing structure 100. LDD regions are next to channel regions and are under spacers. The term LDD regions is used to describe lightly doped regions next to both source and drain regions.

FIG. 1B is a top view of a transistor region 150 formed with one of fins 104 of FIG. 1A and taken on a surface leveled with the top surface 118 of isolation structure 106, in accordance with some embodiments. Transistor region 150 includes a doped source region 110_{S}′ and a doped drain region 110_{D}′, which have the same cross-sections as doped source regions 110_{S} and doped drain region 110_{D}, respectively, of FIG. 1A at surface 118.

Transistor region 150 also includes a channel region 112, which is part of fin 104 and is surrounded by gate structure 108 on three sides, as shown in FIG. 1A. Channel region 112 has a length (gate length) L and a width (gate width) W. Transistor region 150 also includes gate dielectric layer 115 and gate electrode layer 117. FIG. 1B shows LDD regions 113 between source region 110_{S} and channel region 112, and between drain region 110_{D} and channel region 112. LDD regions 113 have a width W and a length L_{S}, which is defined by the width of spacers 111. FIG. 1B shows another gate structure 108 by dotted lines. This other gate structure 108 has been described above as being similar and parallel to gate structure 108 and is not shown in FIG. 1A. In some embodiments, L_{S} is in a range from about 5 nm to about 10 nm.

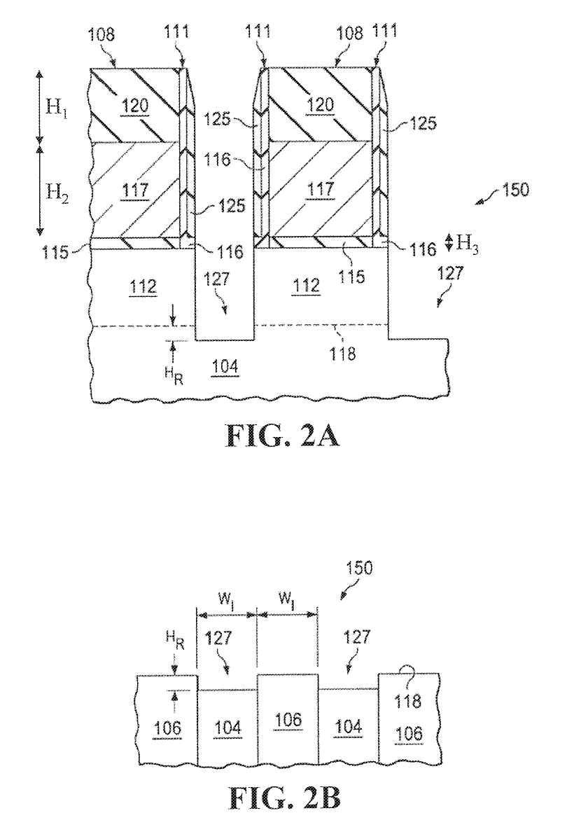

FIGS. 2A and 2B are cross-sectional views of transistor region 150 after recesses 127 are formed, in accordance with some embodiments. Prior to recessing the source and drain regions of p-channel devices, a photolithography process could be used to cover other regions, such as n-channel device regions, on substrate 102, with photoresist to prevent etching. As a result, a resist removal process is needed after the etching process and before the next operation. An additional cleaning process could be used to ensure no residual resist remains on the substrate.

FIG. 2A shows two neighboring gate structures 108 according to the cut 131 illustrated in FIG. 1A, in accordance with some embodiments. As mentioned above, there are additional gate structure(s) similar and parallel to gate structure 108 shown in FIG. 1A. FIG. 2A shows two neighboring gate structures 108 formed over fin 104 and separated by recesses 127, which are formed by etching source/drain regions 110_{D} and 110_{S} of FIG. 1A. For simplicity of discussion, we designate recesses 127 as recessed drain region (110_{D}). Each gate structure 108 includes a gate electrode layer 117 and a gate dielectric layer 115. A hard mask layer 120 is formed over the gate electrode layer 117, in accordance with some embodiments. Hard mask layer 120 is used in assisting patterning of gate structures 108. In some embodiments, the thickness H₁ of hard mask layer 120 is in a range from about 70 nm to about 100 nm. The thickness H₂ of gate electrode layer 117 is in a range from about 80 nm to about 100 nm. The thickness H₃ of gate dielectric layer 115 is in a range from about 2 nm to about 5 nm. The channel length L is shown in FIG. 2A as equal to the width of gate electrode layer 117 of gate structure 108. Channel regions 112, which are directly under gate structures 108 are also noted in FIG. 2A. A dotted line 118 indicates the level of surfaces of isolation regions 106.

FIG. 2A also show spacers 111 formed next to gate structures 108. Spacers 111 include an offset spacer layer 116 and a main spacer layer 125, in accordance with some embodiments. Between neighboring gate structures 108, there are recesses 127. The depth H_{R} of recesses 127 below surface 118 of isolation structures 106 is in a range from about 10 nm to about 20 nm. Recesses 127 may be formed to have either an angular or rounded shape on the bottoms.

FIG. 2B shows a cross-sectional view of transistor region 150 according to the cut 132 illustrated in FIG. 1A, in accordance with some embodiments. FIG. 2B shows recesses 127 in two neighboring recessed fins 104 separated (or isolated) from each other by an isolation structure 106. Each of the two neighboring recessed fins 104 has isolation structures 106 on both sides The distance W₁ between the two neighboring recesses 127 is in a range from about 10 nm to about 20 nm, in some embodiments.

After the recesses 127 are formed, an epitaxial layer is grown in recesses 127 to form doped source and drain regions, 110_{D}′ and 110_{S}′ respectively, at operation 206 of FIG. 2, in accordance with some embodiments. Doped source and drain regions 110_{D}′ and 110_{S}′ are located right next to the LDD regions 113, which are between channel regions 112 and source/drain regions 110_{D}′, 110_{S}′. The dopants in the doped source and drain regions, 110_{D}′, 110_{S}′, could diffuse into and dope the LDD regions 113 by annealing. In order to dope the LDD regions 113, the dopant concentration of the doped source and drain regions 110_{D}′ and 110_{S}′ needs to be much higher than the required dopant concentration of the LDD regions 113. For example, if the dopant level (or concentration) of p-type dopant in the LDD regions 133 is at a value equal to or greater than about 1E20 atoms/cm³, the dopant concentration of the doped source and drain regions should have a value equal to or greater than about 3E20 atoms/cm³.

In some embodiments, the epitaxial material filling recesses 127 to form doped source and drain regions, 110_{D}′ and 110_{S}′, is a silicon-containing material 215. In some embodiments, the epitaxially-grown silicon-containing material 215 is formed by an epitaxial deposition/partial etch process, which repeats the epitaxial deposition/partial etch process at least once. Such repeated deposition/partial etch process is also called a cyclic deposition-etch (CDE) process.

The deposition of silicon-containing material 215 includes in-situ doping the silicon-containing material 215, in accordance with some embodiments. For example, forming an n-channel transistor can use an n-type doping precursor, e.g., phosphine (PH₃) and/or other n-type doping precursor. By using the in-situ doping process, the dopant concentration (or level) of silicon-containing material 215 can be desirably controlled and achieved. In some embodiments, silicon-containing material 215 can be an n-type doped silicon layer that is doped with phosphorus (Si:P). In some embodiments, silicon-containing material 215 can be an n-type doped silicon layer that is doped with both phosphorus and carbon (Si:CP). Carbon could impede the out-diffusion of phosphorus from silicon-containing material 215. In some embodiments, the carbon dopant has a concentration in a range from about 0.1% to about 5% (atomic percent). Other types of dopants may also be included, including various doping precursors and dopants for forming a p-channel transistor, as would be known to a person skilled in the art.

In some embodiments, the silicon-containing material 215 can be formed by CVD, e.g., low pressure CVD (LPCVD), atomic layer CVD (ALCVD), ultrahigh vacuum CVD (UHVCVD), reduced pressure CVD (RPCVD), any suitable CVD; molecular beam epitaxy (MBE) processes; any suitable epitaxial process; or any combinations thereof.

The silicon-containing material 215 in recesses 127 is epitaxial. The deposition process forms a thin epitaxial layer of silicon-containing material in recesses 127 and an amorphous silicon-containing material on non-crystalline surfaces. An etching (or partial etching) process removes the amorphous silicon-containing material and also a portion of the silicon-containing material in recesses 127. The remaining silicon-containing material 215 is formed in each of recesses 127.

In some embodiments, the etching process can use an etching gas including at least one of hydrogen chloride (HCl), chlorine (Cl₂), other suitable etching gases, and/or any combinations thereof. The etching process would remove the amorphous silicon-containing material over non-crystalline surface at a rate higher than the removal rate of epitaxial silicon-containing material 215. Therefore, only epitaxial film remains on the substrate surface after a CDE cycle. The epitaxial deposition/partial etch process is repeated a number of times until a desired thickness is reached. As a result, such repeated deposition/partial etch process is called a cyclic deposition-etch process.

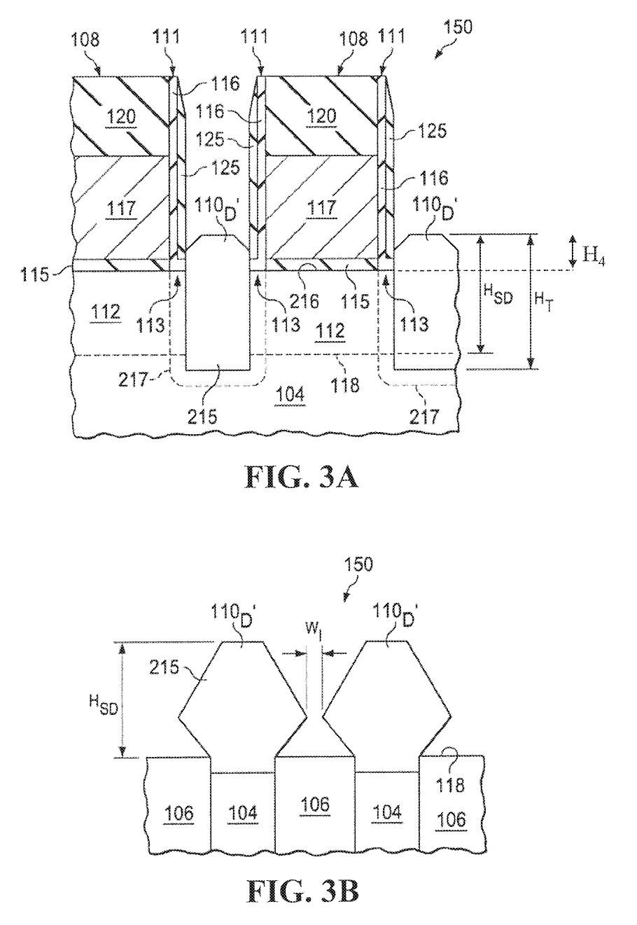

FIGS. 3A and 3B show cross-sectional views of doped drain regions 110_{D}′ formed by CDE process described above, in accordance with some embodiments. The growth rate of epitaxial Si depends on the crystal orientation. Growth rate is slower on closed-packed {111}planes. The doped drain regions 110_{D}′ are made of doped silicon-containing material 215, which also form doped source regions 110_{S}′ (not shown in FIGS. 3A and 3B). In some embodiments, the total thickness H_{T} of epitaxial silicon-containing material 215 is in a range from about 40 nm to about 50 nm. The height (or thickness) H₄ of doped drain regions 110_{D}′ above surface 216 between channel regions 112 and gate dielectric layer 115 is in a range from about 2 nm to about 10 nm, in some embodiments. The height (or thickness) H_{SD} of doped drain regions 110_{D}′ above surface 118 is in a range from about 35 nm to about 45 nm, in some embodiments. The shortest distance W₁ between two neighboring doped drain regions 110_{D}′ is in a range from about 5 nm to about 20 nm, in accordance with some embodiments. Doped source regions 110_{S}′ resemble the doped drain regions 110_{D}′. The description above for doped drain regions 110_{D}′ also applies for doped source regions 110_{S}′.

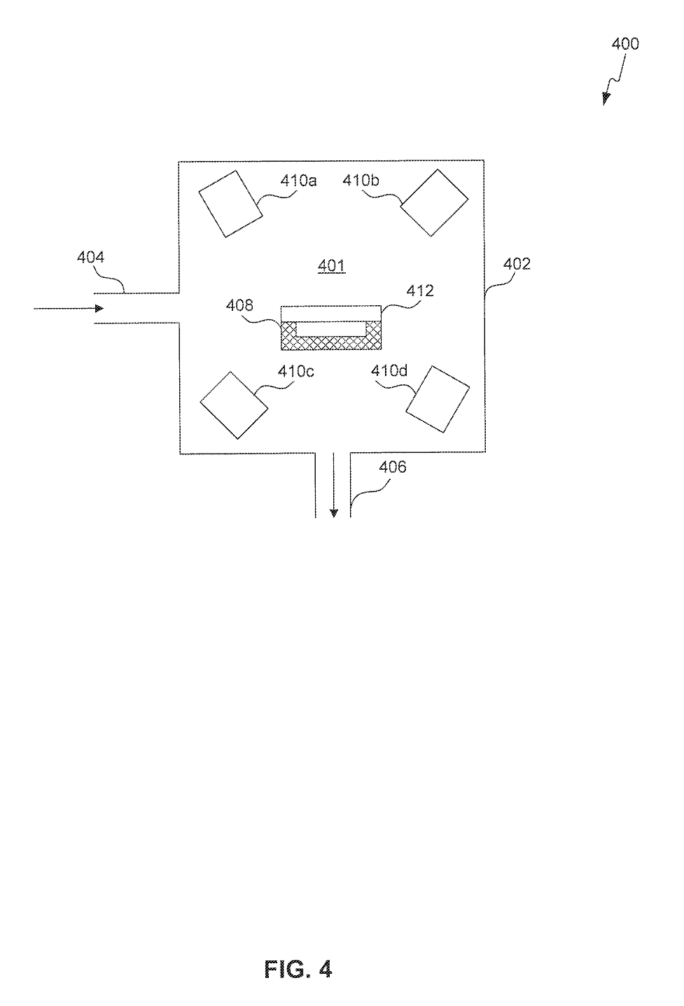

FIG. 4 is a simple block diagram depicting components of an example epitaxial growth chamber 400 that may implement embodiments of the present disclosure. Epitaxial growth chamber 400 may be used to grow the epitaxial material of silicon-containing material 215. It should be understood that the components of epitaxial growth chamber 400 are not provided to scale. A person skilled in the art would recognize that many other components would be included in epitaxial growth chamber 400, but are not included here for clarity.

Epitaxial growth chamber 400 in FIG. 4 may be used to perform epitaxial growth of a material using a chemical vapor deposition (CVD) process. Epitaxial growth chamber 400 includes a housing 402 that defines a main chamber 401, a gas inlet 404, and a gas outlet 406. Gas inlet 404 may represent one or more valved inlets designed to introduce carrier and/or reactive gas into main chamber 401. Gas outlet 406 provides a path for any gases within main chamber 401 to exit.

Within main chamber 401, a susceptor 408 may be used to hold substrate 412. Susceptor 408 may be any material capable of absorbing electromagnetic energy and converting the energy to heat. In one example, susceptor 408 includes graphite. The body of susceptor 408 is thermally conductive and may be shaped to support substrate 412.

Main chamber 401 also includes heating elements 410a-410d. Each heating element 410a-410d may be placed some distance apart from each other and positioned such that the generated heat is focused towards substrate 412. The heating of the gas(es) introduced via inlet 404 cause the epitaxial growth to occur across the exposed surface of substrate 412.

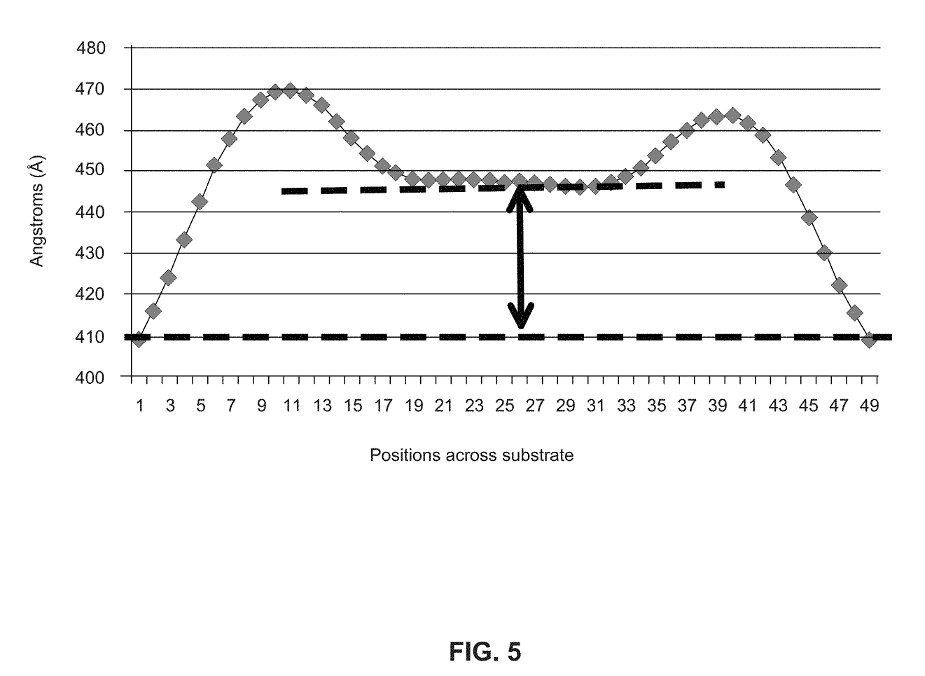

The height H_{T} of epitaxial silicon-containing material 215 may vary depending on the location of semiconductor device structure 100. For example, when the epitaxial growth process for silicon-containing material 215 is occurring within epitaxial growth chamber 400, the location of semiconductor device structure 100 upon the surface of substrate 412 can impact the final height H_{T} of epitaxial silicon-containing material 215. FIG. 5 is a graph showing the measured heights of epitaxially grown structures, such as silicon-containing material 215, taken at points across the diameter of a substrate. In this example, the epitaxial growth was performed at about 625° C., and the substrate is a 12-inch silicon wafer. Also, in this example, the epitaxial material may include some combination of silicon and germanium. The epitaxial material may be p-doped with boron.

As can be seen in FIG. 5, the height of the epitaxially grown structures is fairly consistent in the center of the wafer (from measurement points 17-33). However, the height of the epitaxially grown structures increases by around 25 nm, then sharply decreases by almost 50-60 nm, as one moves close to the edge of the substrate in any direction. This effect occurs because the temperature across the substrate was not uniform during the epitaxial growth process.

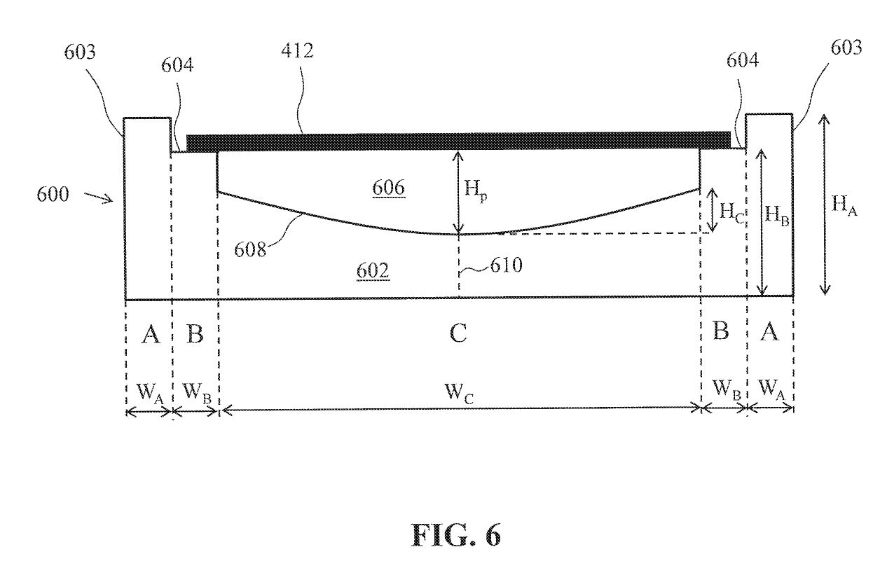

According to an embodiment, a more uniform temperature profile during the epitaxial growth process is achieved by changing the design of susceptor 408. FIG. 6 is a cross-sectional view of a susceptor 600 that is designed to achieve a better temperature profile across substrate 412, according to an embodiment.

Susceptor 600 includes a body 602 having three regions identified by letters A-C. Body 602 may be any thermally conductive material characterized for its ability to absorb electromagnetic radiation and give off heat. Examples of materials for body 602 include ceramics and metals. In another example, body 602 is made from graphite. Body 602 may include a surface coating of silicon carbide (SiC). The boundaries of each region are imaginary and have been marked using dashed lines in FIG. 6. A first region ‘A’ extends from an outer edge 603 of body 602 inwards towards a center 610 of body 602 and has a width W_{A}. Region ‘B’ extends from an inner edge of region ‘A’ inwards towards a center 610 of body 602 and has a width W_{B}. Region C extends from an inner edge of region ‘B’ to center 610 of body 602 and has a total width W_{C}.

Region ‘A’ identifies the outer-most region of susceptor 600 and also has the largest height H_{A} amongst the different regions, according to an embodiment. Region ‘B’ includes a substantially flat and planar surface 604 upon which substrate 412 rests, according to an embodiment. Surface 604 is substantially parallel to a bottom surface of substrate 412, according to an embodiment. A height H_{B} of region ‘B’ is smaller than height H_{A} from region ‘A’. Surface 604 may include a coating to promote better adhesion and reduce slipping of substrate 412. For example, surface 604 may include a silicon carbide coating.

By resting substrate 412 at its edge upon a substantially planar surface 604, heat is transferred to the edge region of substrate 412 via conduction. This design helps to reduce the “edge effect” and create a more uniform temperature profile across the wafer.

Region ‘C’ includes a sloped surface 608 with a decreasing height moving towards center 610, according to an embodiment. Sloped surface 608 has a total height of H_{C}. Region C also includes a pocket region 606 that exists between the lower surface of substrate 412 and sloped surface 608. Pocket region 606 may be included to provide a void beneath substrate 412, which can further improve the temperature uniformity across substrate 412. Pocket region 606 has a depth Hₚ between center 610 of sloped surface 608 and the bottom surface of substrate 412. Depth Hₚ may be decreased due to the design of having substrate 412 sit on a planar surface 604. In an embodiment, holes may be present through body 602 in region ‘C’ to allow gas to escape from within pocket region 606. In another example, gas may be pumped into pocket region 606 via the holes through body 602 in region ‘C’.

The following values for the various dimensions in susceptor 600 are provided as examples. Width W_{A} of region ‘A’ may be in a range from about 20 mm to about 80 mm. Width W_{B} of region ‘B’ may be in a range from about 1 mm to about 40 mm. Width W_{B} may be 10 mm. Width W_{C} may be in a range from about 80 mm to about 300 mm, or from about 260 mm to about 300 mm. Height H_{A} may be in a range from about 2.8 mm to about 4.8 mm. Height H_{B} may be in a range from about 1.6 mm to about 3.6 mm. Height He may be in a range from about 0.1 mm to about 5 mm. Pocket depth Hₚ may be in a range from about 0.05 mm to about 0.4 mm.

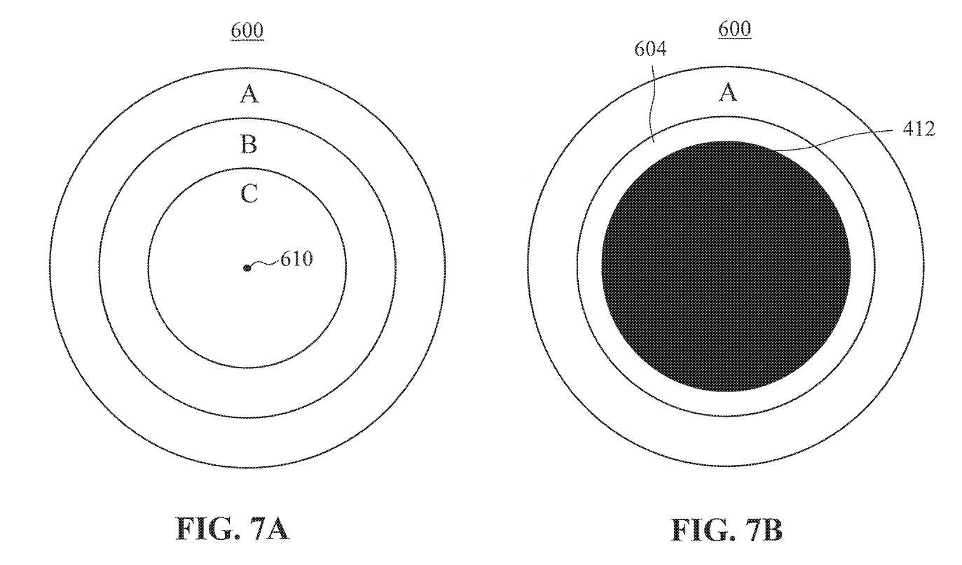

FIGS. 7A and 7B illustrate a top-down view of susceptor 600, according to some embodiments. FIG. 7A illustrates the top-down view of susceptor 600 without having a substrate, while FIG. 7B illustrates the top-down view of susceptor 600 with substrate 412 placed on surface 604 in region ‘B’. Each region A-C defines a concentric circle around center 610, according to an embodiment.

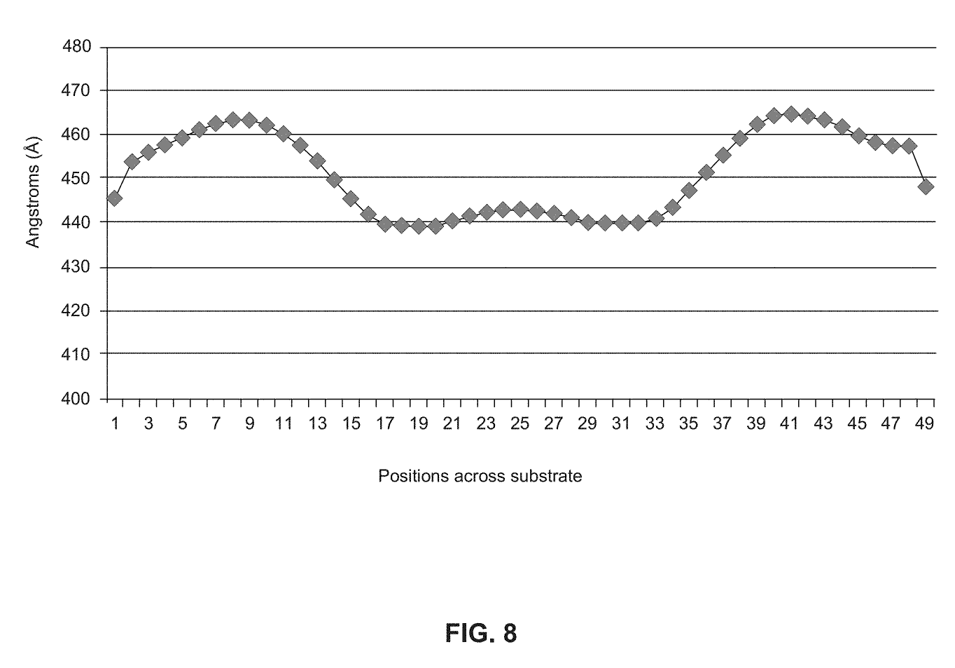

FIG. 8 is another graph showing the measured heights of epitaxially grown structures, such as silicon-containing material 215 from semiconductor device structure 100, taken at points across the diameter of a substrate. The experimental conditions are similar to those used when measuring the heights shown in FIG. 5, except that the heights measured and plotted in FIG. 8 are from a substrate that rested upon the susceptor design illustrated in FIG. 6 during the epitaxial growth process. As can be seen, the heights of the epitaxially grown structures at the edges of the wafer do not drop off as much as the heights shown in FIG. 5. This improvement in the epitaxial growth uniformity may be attributed to the improved design of the susceptor as described above.

It should be understood that although the design of body 602 to hold substrate 412 is described in the context of being a susceptor for use in an epi growth system, such a design is not limited to only applications of epitaxial growth. Body 602 may be used as any thermally conductive chuck in a variety of different applications.

There are many benefits to the improved susceptor design beyond the improvement to epitaxial growth uniformity across a substrate. The improved susceptor design promotes better thermal stability during the heating of the substrate and reduces processing time since recipe tuning is no longer required to make up for a non-uniform temperature profile. The improved susceptor design may also increase the lifetime of the heat sources used within the epi growth chamber, since there is no longer a need to drive certain heat sources with higher current to make up for a non-uniform temperature profile. Using the improved susceptor design results in a higher device yield across the substrate and more uniform device characteristics for transistors patterned across the substrate.

In one embodiment, a susceptor for use in an epitaxial growth chamber includes a thermally conductive body designed to hold a substrate. The thermally conductive body includes a first region, a second region, and a third region. The first region extends from an outer edge of the thermally conductive body inwards towards a center of the thermally conductive body at a first width, the first region having a first height. The second region extends from an inner edge of the first region inwards towards the center of the thermally conductive body at a second width, the second region having a second height lower than the first height. The third region extends from an inner edge of the second region to the center of the thermally conductive body. The second region includes a planar surface that is substantially parallel to a bottom surface of the substrate and a portion of the bottom surface of the substrate rests upon the planar surface of the second region.

In another embodiment, a thermally conductive chuck is designed to hold a wafer and includes a first region, a second region, and a third region. The first region extends from an outer edge of the chuck inwards towards a center of the chuck at a first width, the first region having a first height. The second region extends from an inner edge of the first region inwards towards the center of the chuck at a second width, the second region having a second height lower than the first height. The third region extends from an inner edge of the second region to the center of the chuck. The second region includes a planar surface that is substantially parallel to a bottom surface of the wafer and a portion of the bottom surface of the substrate rests upon the planar surface of the second region.

It is to be appreciated that the Detailed Description section, and not the Abstract section, is intended to be used to interpret the claims. The Abstract section may set forth one or more but not all exemplary embodiments of the present invention as contemplated by the inventor(s), and thus, is not intended to limit the present disclosure and the appended claims in any way.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present disclosure. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of its teachings and guidance.

The breadth and scope of the present invention should not be limited by any of the above-described exemplary embodiments, but should be defined only in accordance with the following claims and their equivalents.

What is claimed is:

1. A susceptor for use in an epitaxial growth chamber, the susceptor comprising:
a thermally conductive body configured to hold a substrate, the thermally conductive body comprising:
a first region extending from an outer edge of the thermally conductive body inwards towards a center of the thermally conductive body at a first width, the first region having a first height;
a second region extending from an inner edge of the first region inwards towards the center of the thermally conductive body at a second width, the second region having a second height lower than the first height; and
a third region extending from an inner edge of the second region to the center of the thermally conductive body,
wherein the second region includes a planar surface that is substantially parallel to a bottom surface of the substrate, and wherein a portion of the bottom surface of the substrate rests upon the planar surface of the second region.

2. The susceptor of claim 1, wherein the second width is between 1 mm and 40 mm.

3. The susceptor of claim 1, wherein the third region includes a sloped surface having a decreasing height from the inner edge of the second region to the center of the thermally conductive body.

4. The susceptor of claim 3, wherein a distance between the bottom surface of the substrate and the sloped surface at the center of the thermally conductive body is between 0.05 mm and 0.4 mm.

5. The susceptor of claim 3, wherein a height of the sloped surface is between 0.1 mm and 5 mm.

6. The susceptor of claim 1, wherein the thermally conductive body comprises graphite, and wherein the planar surface of the second region includes a coating comprising silicon carbide.

7. A thermally conductive chuck configured to hold a wafer, the chuck comprising:
a first region extending from an outer edge of the chuck inwards towards a center of the chuck at a first width, the first region having a first height;
a second region extending from an inner edge of the first region inwards towards the center of the chuck at a second width, the second region having a second height lower than the first height; and
a third region extending from an inner edge of the second region to the center of the chuck,
wherein the second region includes a planar surface that is substantially parallel to a bottom surface of the wafer, and wherein a portion of the bottom surface of the wafer rests upon the planar surface of the second region.

8. The thermally conductive chuck of claim 7, wherein the second width is between 1 mm and 40 mm.

9. The thermally conductive chuck of claim 7, wherein the third region includes a sloped surface having a decreasing height from the inner edge of the second region to the center of the chuck.

10. The thermally conductive chuck of claim 9, wherein a distance between the bottom surface of the wafer and the sloped surface at the center of the chuck is between 0.05 mm and 0.4 mm.

11. The thermally conductive chuck of claim 9, wherein a height of the sloped surface is between 0.1 mm and 5 mm.

12. The thermally conductive chuck of claim 7, wherein the second region comprises graphite, and wherein the planar surface of the second region includes a coating comprising silicon carbide.
